(19) United States
(12) Patent Application Publication
(10) Pub. No.: US 2025/0192747 A1
(43) Pub. Date: Jun. 12, 2025

(54) INTEGRATED NOISE FILTER

(71) Applicant: MOTIVELINK CO.,Ltd, Yongin-si (KR)

(72) Inventors: Hyung Suk SONG, Cheonan-si (KR); Ji Seok SON, Anyang-si (KR); Jong Kyu KIM, Hwaseong-si (KR)

(73) Assignee: MOTIVELINK CO.,Ltd, Yongin-si (KR)

(21) Appl. No.: 19/060,828

(22) Filed: Feb. 24, 2025

Related U.S. Application Data
(63) Continuation of application No. PCT/KR2023/010934, filed on Jul. 27, 2023.

(30) Foreign Application Priority Data
Jul. 26, 2023 (KR) 10-2023-0097158

(51) Int. Cl. H03H 7/01; H02G 5/02

(52) U.S. Cl. CPC H03H 7/0115; H02G 5/02

(57) ABSTRACT

An integrated noise filter according to a disclosed embodiment of the present disclosure may include a busbar unit which transmits power and an electrical signal, a case unit which accommodates and covers at least a part of the busbar unit, at least one core unit which covers a part of an outer surface of the busbar unit and imparts inductance to the busbar unit, and at least one energy storage unit electrically connected to the busbar unit to impart capacitance to the busbar unit.

### CROSS-REFERENCE TO RELATED APPLICATIONS

This application is a continuation application of International Application No. PCT/KR2023/010934, filed Jul. 27, 2023, which claims the benefit of Korean Patent Application No. 10-2023-0097158, filed Jul. 26, 2023 in the Korean Intellectual Property Office, the disclosures of which are incorporated herein in their entirety by reference.

### TECHNICAL FIELD

The present disclosure relates to an integrated noise filter, and more specifically, to an integrated noise filter which removes electromagnetic interference (EMI) and is integrated with a connector.

### BACKGROUND ART

To improve the quality of power supplied to electronic products and the like and implement the stable operations of the electronic products, the importance of a filter for removing or minimizing electromagnetic interference (EMI) noise is continuously increasing.

In particular, in a mobility field, hybrid electric vehicles (HEVs), plug-in HEVs (PHEVs), electric vehicles (EVs), and fuel cell vehicles (FCEVs) are attracting attention as future eco-friendly vehicles which will replace fossil fuel-powered vehicles.

In relation to electric vehicles that are currently being actively commercialized, various types of power conversion devices are used. For example, an on board charger (OBD) for charging a high-voltage battery from the outside may be used. As another example, a low voltage DC-DC converter (LDC) for converting power from a high-voltage battery to a low-voltage battery (e.g., a 12 V low-voltage battery) may be used.

During a process of charging a high-voltage battery from the outside or converting power from the high-voltage battery to a low-voltage battery, EMI noise may be generated, maintained, and amplified, and such EMI noise may affect power transmission and supply and cause malfunction of loads (e.g., a headlight, a wiper, an electronic controller unit (ECU), and the like which are driven by power supplied from the low-voltage battery) which receive power.

To solve such problems, in the related art, a connector, a differential mode (DM) filter, and a common mode (CM) filter are separately provided and connected to remove EMI noise which is introduced and discharged. However, since the connector, the DM filter, and the CM filter are connected using a busbar and ground due to a high current, there is a high possibility that power loss and noise will occur at connected portions.

In addition, a filter structure which removes EMI noise (e.g., CM noise) using a frame ground (FG) rather than the DM filter has been proposed, but there is a continuous demand for a filter structure which can remove noise more effectively.

### Technical Problem

To solve the above problems, disclosed embodiments of the present disclosure are directed to providing an integrated noise filter which is capable of minimizing electromagnetic interference (EMI) noise introduced from the outside or generated from equipment.

In addition, disclosed embodiments of the present disclosure are directed to providing an integrated noise filter which is capable of being integrated and miniaturized, thereby improving and stability and assemblability miniaturizing the overall power conversion device.

In addition, disclosed embodiments of the present disclosure are directed to providing an integrated noise filter which is customized according to a specification of a target product and optimized to EMI noise.

Objects of the present disclosure are not limited to the above-described objects, and other objects that are not mentioned will be able to be clearly understood by those skilled in the art from the following description.

### Technical Solution

To solve the above problems, an integrated noise filter according to a disclosed embodiment of the present disclosure may include a busbar unit which transmits power and an electrical signal, a case unit which accommodates and covers at least a part of the busbar unit, at least one core unit which covers a part of an outer surface of the busbar unit and imparts inductance to the busbar unit, and at least one energy storage unit electrically connected to the busbar unit to impart capacitance to the busbar unit.

In addition, the busbar unit may include a first input/output terminal electrically connected to an outside, and a second input/output terminal formed opposite to the first input/output terminal and electrically connected to a load.

In addition, the busbar unit may further include a busbar stepped portion which forms a step between the first input/output terminal and the second input/output terminal, and a first bending distance from the busbar stepped portion to an end of the first input/output terminal may be formed to be shorter than a second bending distance from the busbar stepped portion to an end of the second input/output terminal.

In addition, the busbar unit may further include a busbar branch part formed to protrude a predetermined length from one side of a busbar main body including the first input/output terminal and the second input/output terminal, and at least a part of the busbar branch part may be formed to extend in a direction from the second input/output terminal to the first input/output terminal.

In addition, the core unit may include a first core unit configured to apply first inductance to the busbar unit, and a second core unit configured to apply second inductance to the busbar unit, and the first core unit and the second core unit may be disposed to be spaced apart from each other by the busbar branch part.

In addition, the first core unit and the second core unit may form a concentric structure, and each of the first core unit and the second core unit may be formed to be spaced apart from the busbar unit.

In addition, the case unit may include a first busbar unit accommodation part which accommodates the first input/output terminal of the busbar unit, and a second busbar unit accommodation part which accommodates the second input/output terminal of the busbar unit.

In addition, the first busbar unit accommodation part and the second busbar unit accommodation part may each be formed to be open in a direction corresponding to a different axis.

In addition, the case unit may further include a core unit accommodation unit accommodating the at least one core unit so that a center of the at least one core unit corresponds to a center of the busbar unit in an axial direction, and the core unit accommodation part may be formed to be open in a direction corresponding to the same axis as the second busbar unit accommodation part.

In addition, the case unit may further include an energy storage unit accommodation part which accommodates the at least one energy storage unit, and the energy storage unit accommodation unit may be formed to be open in a direction corresponding to the same axis as the first busbar unit accommodation part and formed to be open in a direction corresponding to a different axis from the second busbar unit accommodation part.

In addition, the energy storage unit accommodation part may be formed to be open in a direction opposite to the second busbar unit accommodation part.

In addition, the integrated noise filter may further include a pair of grounding units electrically connected to at least a part of the busbar unit to form a ground, wherein a first grounding unit of the pair of grounding units may be electrically connected to the busbar branch part by both ends of the first energy storage unit of the at least one energy storage unit to form a first grounding path, and a second grounding unit of the pair of grounding units is electrically connected to a first input/output terminal fastening unit fastened to the first input/output terminal of the busbar unit by both ends of the second energy storage unit of the at least one energy storage unit and formed to protrude to one side thereof to form a second grounding path.

In addition, the case unit may further include a pair of grounding unit accommodation parts which are formed to be open in a direction corresponding to the same axis as the second busbar unit accommodation part accommodating the second input/output terminal of the busbar unit and each accommodate one of the pair of grounding units.

In addition, the integrated noise filter may further include a pair of grounding units electrically connected to at least a part of the busbar unit to form a ground, wherein a first grounding unit of the pair of grounding units may be electrically connected to one end of a capacitor connection unit, which is fixed to the first input/output terminal of the busbar unit by the first input/output terminal fastening unit, by both ends of the first energy storage unit of the at least one energy storage unit to form a first grounding path, and a second grounding unit of the pair of grounding units is electrically connected to the other end of the capacitor connection unit by both ends of the second energy storage unit of the at least one energy storage unit to form a second grounding path.

In addition, the at least one core unit may be accommodated in the case unit and then molded, and a ring-shaped elastic member may be disposed between a part of an inner surface of the case unit and a molded outer surface of the at least one core unit.

### Advantageous Effects

According to the proposed embodiments, according to the integrated noise filter according to the disclosed embodiments of the present disclosure, it is possible to minimize EMI noise introduced from the outside or generated from the equipment, thereby reducing bidirectional input/output noise.

In addition, according to the integrated noise filter according to the disclosed embodiments of the present disclosure, it is possible to miniaturize the power conversion device including the integrated noise filter and also miniaturize the electrode product including the power conversion device.

In addition, according to the integrated noise filter according to the disclosed embodiments of the present disclosure, it is possible to customize inductance and/or capacitance according to the specification of the target product, thereby efficiently reducing EMI noise.

### DESCRIPTION OF DRAWINGS

FIG. 1 is a view for describing a state in which an integrated noise filter according to the disclosed embodiment of the present disclosure is coupled to a load and the like.

FIG. 2 is a perspective view of the integrated noise filter according to one disclosed embodiment of the present disclosure.

FIG. 3 is a bottom view of the integrated noise filter according to one disclosed embodiment of the present disclosure.

FIG. 4 is a front view of the integrated noise filter according to one disclosed embodiment of the present disclosure.

FIG. 5 is a circuit diagram of an element configuration between a first input/output terminal and a second input/output terminal in the integrated noise filter according to one disclosed embodiment of the present disclosure.

FIG. 6 is a schematic flowchart of a method of manufacturing the integrated noise filter according to one disclosed embodiment of the present disclosure.

FIGS. 7 to 15 are views for describing the method of manufacturing the integrated noise filter according to one embodiment of the present disclosure.

FIG. 16 is a perspective view of the integrated noise filter according to another disclosed embodiment of the present disclosure.

FIG. 17A is a top view of the integrated noise filter according to another disclosed embodiment of the present disclosure, and FIG. 17B is a bottom view of the integrated noise filter according to another disclosed embodiment of the present disclosure.

FIG. 18 is a front view of the integrated noise filter according to another disclosed embodiment of the present disclosure.

FIG. 19 is an exploded perspective view of the integrated noise filter according to another disclosed embodiment of the present disclosure.

### DESCRIPTION OF REFERENCE NUMERALS

1, 2: integrated noise filters
100: busbar unit 200: case unit
300: core unit 400: energy storage unit
500: grounding unit 600: first input/output terminal fastening unit
700, 700′: capacitor connection units 800: elastic member

### MODE FOR INVENTION

Advantages and features of the present disclosure and methods for achieving them will become clear with reference to embodiments described below in detail together with the accompanying drawings. However, the present disclosure is not limited to the embodiments disclosed below but can be implemented in various different forms, the embodiments are merely provided to make the disclosure of the present disclosure complete and fully inform those skilled in the art to which the present disclosure pertains of the scope of the present disclosure, and the present disclosure is only defined by the scope of the appended claims.

Although “first,” “second,” etc. are used to describe various components, these components are not limited by these terms. The terms are only used to distinguish one component from another. Accordingly, it is apparent that a first component described below may be a second component within the technical spirit of the present disclosure.

The same reference number denotes the same components throughout the specification.

Features of various embodiments of the present disclosure can be partially or fully coupled or combined, and as can be fully understood by those skilled in the art, various technical interconnections and operations are possible, and the embodiments can be implemented independently of each other and implemented together in combination thereof.

Meanwhile, provisional effects that can be expected by the technical features of the present disclosure which are not specifically mentioned in the specification of the present disclosure are treated as described in the present specification, and the present embodiment is provided to more completely describe the present disclosure to those skilled in the art, and thus the contents illustrated in the drawings can be expressed in an exaggeration manner in comparison to the actual implementation of the invention, configuration which is and detailed description of a determined to unnecessarily obscure the gist of the present disclosure will be omitted or briefly given.

Hereinafter, disclosed embodiments of the present disclosure will be described in detail with reference to the accompanying drawings.

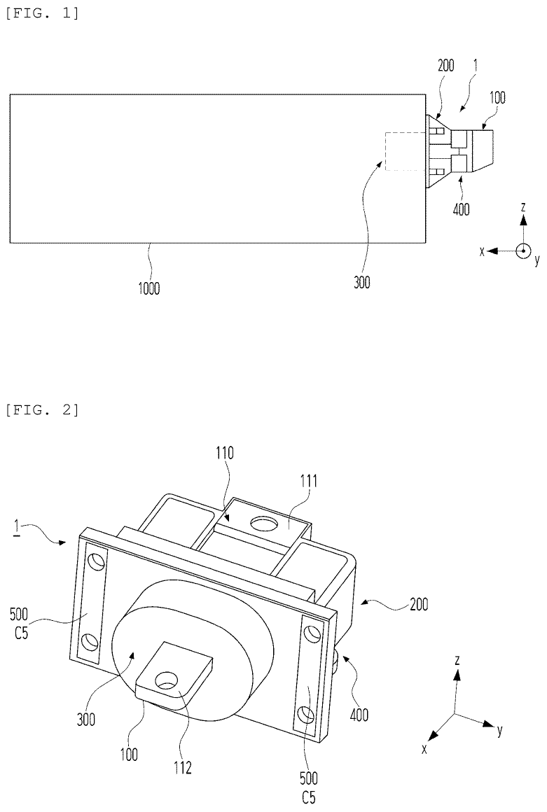

FIG. 1 is a view for describing a state in which an integrated noise filter 1 according to the disclosed embodiment of the present disclosure is coupled to a load 1000 and the like.

Referring to FIG. 1, the integrated noise filter 1 according to the disclosed embodiment of the present disclosure may be joined and coupled to one side of the load 1000. In FIG. 1, the load 1000 is schematically illustrated, but may be a component which receives power. For example, the load 1000 may be at least one of components for an electric vehicle, such as a headlight, a wiper, and an electronic controller unit (ECU), which receive power from a low-power battery of the electric vehicle.

The integrated noise filter 1 according to the disclosed embodiment of the present disclosure may perform a function of a filter for filtering noise. In addition, the integrated noise filter 1 according to the disclosed embodiment of the present disclosure may also simultaneously perform a function of a connector which connects any load(s) to other load(s), connects a high-voltage battery to a low-voltage battery, or connects the low-voltage battery to the load(s). That is, it can be understood that the integrated noise filter 1 according to the disclosed embodiment of the present disclosure is formed by integrating a noise filter and a connector.

Hereinafter, detailed components of the integrated noise filter 1 according to the disclosed embodiment of the present disclosure will be described in detail.

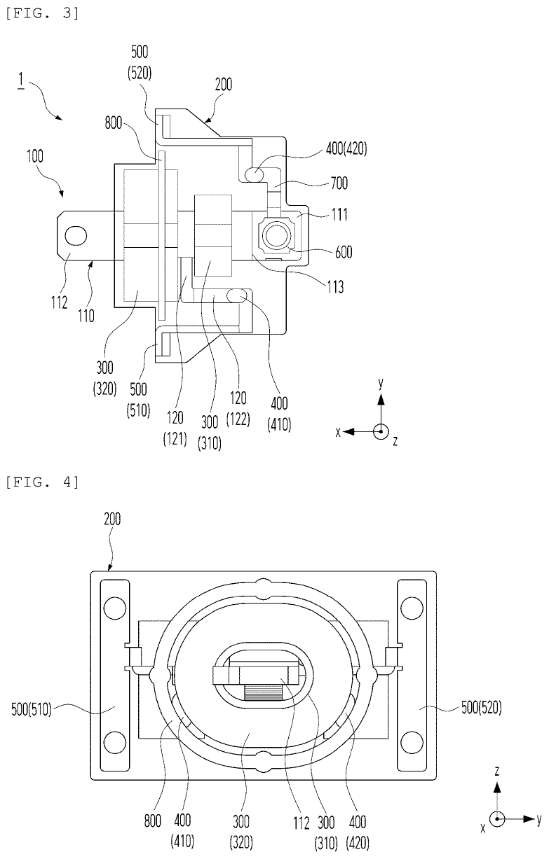

FIG. 2 is a perspective view of the integrated noise filter 1 according to one disclosed embodiment of the present disclosure, FIG. 3 is a bottom view of the integrated noise filter 1 according to one disclosed embodiment of the present disclosure, and FIG. 4 is a front view of the integrated noise filter 1 according to one disclosed embodiment of the present disclosure.

Referring to FIGS. 1 to 4, the integrated noise filter 1 according to the disclosed embodiment of the present disclosure may include a busbar unit 100. The busbar unit 100 may be formed of an electrically conductive material and may serve to transmit power and an electrical signal. The busbar unit 100 may transmit power in one direction or both directions to supply electrical energy to a load and the like which require power and transmit an electrical signal in one direction or both directions so that a specific component is operated and/or controlled. For example, the busbar unit 100 may be plated with copper, but a method of forming the busbar unit 100 is not limited to the above-described example.

Both ends of the busbar unit 100 may be electrically connected to the outside and/or a load, but when the busbar unit 100 is entirely exposed, the busbar unit 100 may be affected by an external environment (e.g., a change in impedance), and noise generation, noise amplification, signal distortion, and power loss may occur. To minimize the influence of such an external environment, the integrated noise filter 1 according to the disclosed embodiment of the present disclosure may include a case unit 200. The case unit 200 may accommodate and cover at least a part of the busbar unit 100. For example, the case unit 200 may accommodate and cover the remaining portions except for parts of both ends of the busbar unit 100. Accordingly, the case unit 200 can minimize the influence of the busbar unit 100 from the external environment. A specific structure of the case unit 200 will be described below.

Meanwhile, to remove noise from the power, signal, and/or radiant noise transmitted by the busbar unit 100, predetermined inductance L may be applied to the busbar unit 100. The integrated noise filter 1 according to the disclosed embodiment of the present disclosure may include at least one core unit 300, and the at least one core unit 300 may cover a part of an outer surface of the busbar unit 100 and provide inductance to the busbar unit 100. The at least one core unit 300 may have a ring shape, and at least a part of the busbar unit 100 may pass through the inside of a communication hole formed to communication with the at least one core unit 300. For example, the at least one core unit 300 may be a magnet having an electromagnetic force, and the power, signal, and radiant noise transmitted through the busbar unit 100 can be reduced by the electromagnetic force applied by the at least one core unit 300 to the busbar unit 100.

In addition, predetermined capacitance C may be applied to the busbar unit 100 to remove noise from the power and signal transmitted by the busbar unit 100. The integrated noise filter 1 according to the disclosed embodiment of the present disclosure may include at least one energy storage unit 400, and the at least one energy storage unit 400 may be electrically connected to the busbar unit 100 to impart capacitance to the busbar unit 100. For example, the at least one energy storage unit 400 may be a Y capacitor for an EMC filter, but is not necessarily limited to the disclosed example. The at least one energy storage unit 400 can reduce power noise, signal noise, and radiation noise transmitted through the busbar unit 100 by the capacitance imparted to the busbar unit 100.

Hereinafter, a structure of the integrated noise filter 1 according to the disclosed embodiment of the present disclosure from a circuit perspective will be described.

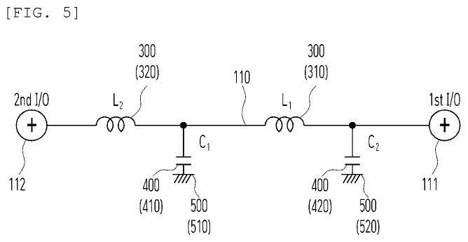

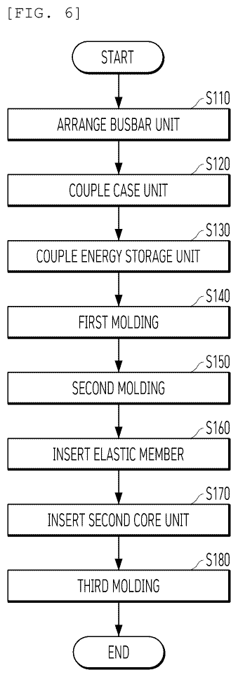

FIG. 5 is a circuit diagram of an element configuration between a first input/output terminal 111 and a second input/output terminal 112 in the integrated noise filter 1 according to one disclosed embodiment of the present disclosure.

Referring to FIGS. 2 to 5 (particularly, FIG. 5), the busbar unit 100 in the integrated noise filter 1 according to the disclosed embodiment of the present disclosure may form a moving path for power and/or a signal. For example, in the integrated noise filter 1, both ends of the busbar unit 100 may be electrically connected by being joined to the outside and/or a load. For example, one end of the busbar unit 100 may be electrically connected by being joined to the outside, and the other end opposite to the one end of the busbar unit 100 may be electrically connected by being joined to the load.

In this case, the at least one core unit 300 for imparting the predetermined inductance L may be disposed between the both ends of the busbar unit 100, and the at least one energy storage unit 400 for imparting the predetermined capacitance C may be disposed between the both ends of the busbar unit 100.

For example, in the integrated noise filter 1 according to the disclosed embodiment of the present disclosure, a first core unit 310 included in the at least one core unit 300 may impart first inductance L1 to the busbar unit 100, and a second core unit 320 included in the at least one core unit 300 may impart second inductance L2 to the busbar unit 100.

In addition, for example, in the integrated noise filter 1 according to the disclosed embodiment of the present disclosure, a first energy storage unit 410 included in the at least one energy storage unit 400 may impart first inductance C1 to the busbar unit 100, and a second energy storage unit 420 included in the at least one energy storage unit 400 may impart energy storage inductance C2 to the busbar unit 100.

In this way, the power noise, signal noise, and radiant noise transmitted through the busbar unit 100 may be controlled and effectively reduced by the inductances L1 and L2 and capacitances C1 and C2 provided to the busbar unit 100.

For example, the first inductance L1 of the first core unit 310 may be 0.04 μH, and the second inductance L2 of the second core unit 320 may be 0.32 μH. In addition, the first capacitance C1 of the first energy storage unit 410 may be 4.7 μF, and the second capacitance C2 of the second energy storage unit 420 may be 4.7 μF. However, values of the first inductance L1 of the first core unit 310, the second inductance L2 of the second core unit 320, the first capacitance C1 of the first energy storage unit 410, and the second capacitance C2 of the second energy storage unit 420 are illustrative, and optimal values of the core unit 300 and the energy storage unit 400 may be used to effectively reduce noise in a device to which the integrated noise filter 1 according to the disclosed embodiment of the present disclosure is applied.

Hereinafter, a process of manufacturing the integrated noise filter 1 according to the disclosed embodiment of the present disclosure will be described.

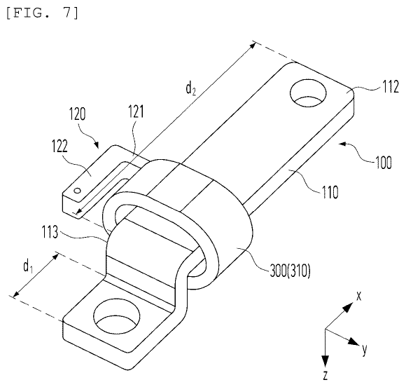

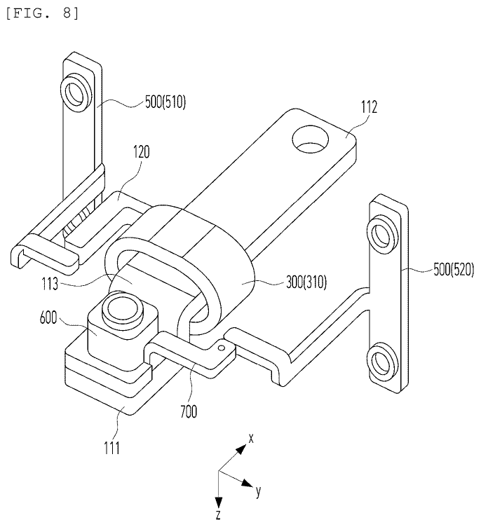

FIG. 6 is a schematic flowchart of a method of manufacturing the integrated noise filter 1 according to one disclosed embodiment of the present disclosure, and FIGS. 7 to 15 are views for describing the method of manufacturing the integrated noise filter 1 according to one embodiment of the present disclosure.

Referring to FIG. 6, a method of manufacturing the integrated noise filter 1 according to one disclosed embodiment of the present disclosure may include a busbar unit arranging operation S110, a case unit coupling operation S120, an energy storage unit coupling operation S130, a first molding operation S140, a second molding operation S150, an elastic member inserting operation S160, a second core unit inserting operation S170, and a third molding operation S180.

As illustrated in FIGS. 6 and 7, the busbar unit 100 may be provided in the busbar unit arranging operation S110. In some embodiments, the busbar unit 100 may include a busbar branch part 120, and the first core unit 310 among the at least one core unit 300 may be disposed at one side of the busbar branch part 120.

Thereafter, as illustrated in FIGS. 6 and 8, a pair of grounding units 500 may be disposed adjacent to the busbar unit 100. The pair of grounding units 500 may form a ground path along which noise included in the power and/or signal transmitted through the busbar unit 100 move. At least one of the pair of grounding units 500 may be disposed adjacent to the busbar branch part 120 of the busbar unit 100, and the other of the pair of grounding units 500 may be disposed adjacent to a capacitor connection unit 700 disposed at one end of the busbar unit 100.

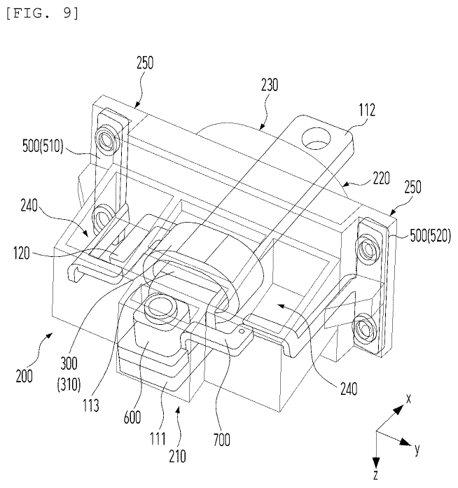

Thereafter, as illustrated in FIGS. 6 and 9, in the case unit coupling operation S120, the busbar unit 100 may be covered by the case unit 200. For example, the case unit 200 may be manufactured by insert injection molding using a plastic material, but is not necessarily limited to the injection molding method.

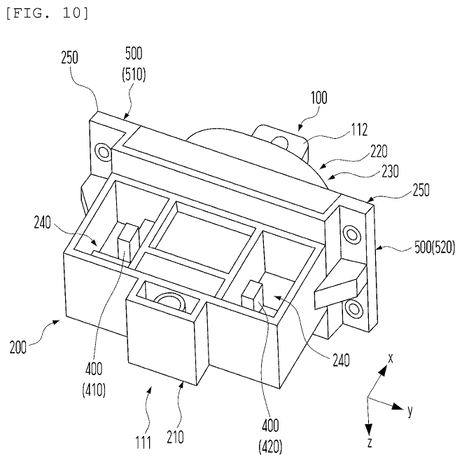

As illustrated in FIGS. 6 and 10, in the energy storage unit coupling operation S130, the at least one energy storage unit 400 may be coupled to the busbar unit 100 to electrically connect the busbar unit 100 to the pair of grounding units 500. For example, one end of the first energy storage unit 410 among the at least one energy storage unit 400 may be connected to the busbar branch part 120, the other end of the first energy storage unit 410 may be connected to a first grounding unit 510 among the pair of grounding units 500, and each of both ends of the first energy storage unit 410 may be soldered to the busbar branch part 120 and the first grounding unit 510. As another example, one end of the second energy storage unit 420 among the at least one energy storage unit 400 may be connected to the capacitor connection unit 700, the other end of the second energy storage unit 420 may be connected to a second grounding unit 520 among the pair of grounding units 500, and each of both ends of the second energy storage unit 420 may be soldered to the capacitor connection unit 700 and the second grounding unit 520.

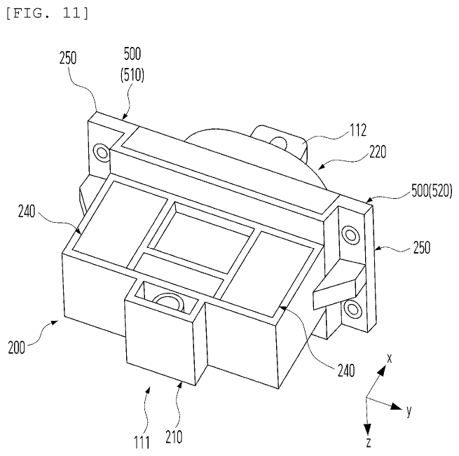

As illustrated in FIGS. 6 and 11, in the first molding operation S140, a portion of the case unit 200 in which the at least one energy storage unit 400 is accommodated may be molded. Accordingly, the at least one energy storage unit 400 can be protected from an external environment by the first molding operation S140.

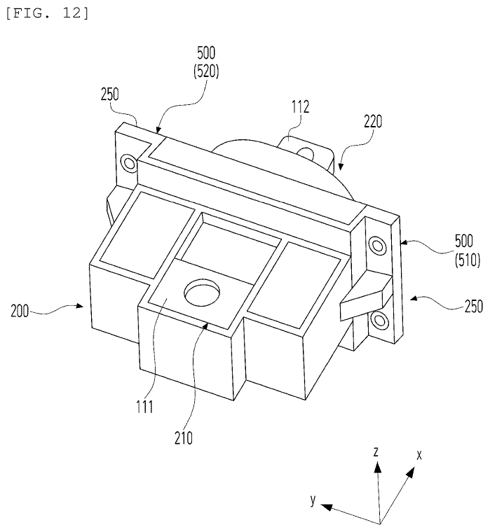

As illustrated in FIGS. 6 and 12, in the second molding operation S150, a portion of the case unit 200 in which the busbar unit 100 is accommodated may be molded. Accordingly, the remaining portions of the busbar unit 100 excluding both ends can be protected from the external environment by the second molding operation S150.

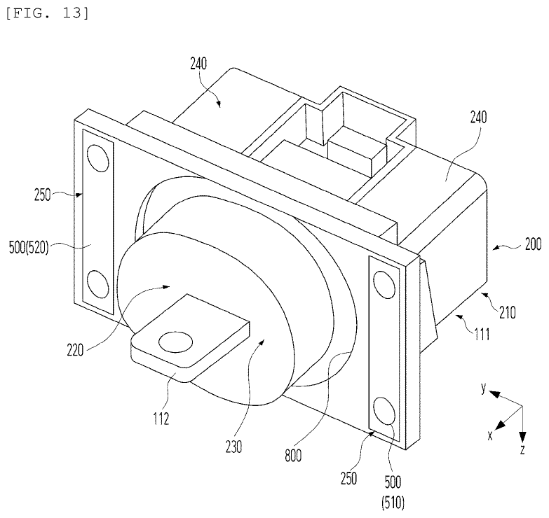

As illustrated in FIGS. 6 and 13, in the elastic member inserting operation S160, an elastic member 800 may be inserted and disposed. For example, the elastic member 800 may be disposed on an inner surface of the case unit 200 and can minimize a clearance so that components disposed inside the case unit 200 are disposed at right positions.

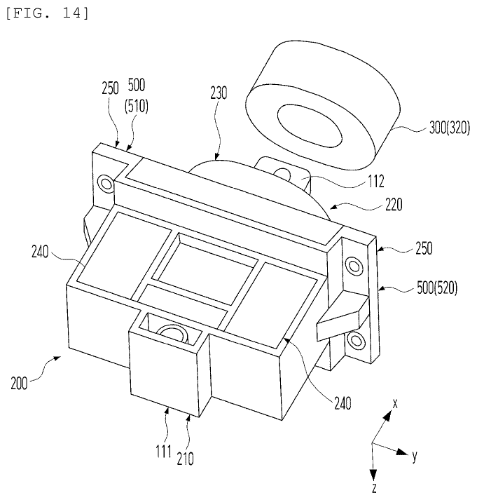

As illustrated in FIGS. 6 and 14, in the second core unit inserting operation S170, the second core unit 320 among the at least one core unit 300 may be inserted. More specifically, the second core unit 320 may be disposed inside the case unit 200 in which the busbar unit 100 is disposed, and thus the second core unit 320 may impart the second inductance L2 to the busbar unit 100.

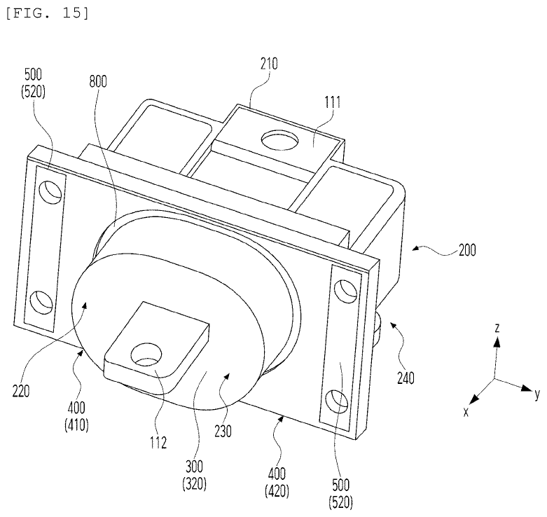

As illustrated in FIGS. 6 and 15, in the third molding operation S180, the second core unit 320 may be molded. That is, the second core unit 320 may be fixedly molded in the third molding operation S180 not to be separated to the outside. Meanwhile, an outer surface of the molded portion in the third molding operation $180 may be in contact with the elastic member 800. Accordingly, the second core unit 320 may be disposed at a right position, and the molded portion may be in contact with the elastic member 800 to implement a stable and miniaturized structure of the noise filter.

Hereinafter, by selectively referring to drawings for describing the method of manufacturing the integrated noise filter 1, specific components of the integrated noise filter 1 according to the disclosed embodiment of the present disclosure will be described.

Referring to FIG. 7, the busbar unit 100 of the integrated noise filter 1 according to the disclosed embodiment of the present disclosure may include a busbar main body 110. The busbar main body 110 may serve to transmit power and/or a signal. Both ends of the busbar main body 110 may each be connected to one of a component (e.g., a low-power battery) for supplying power and a load.

More specifically, the busbar unit 100 may include the first input/output terminal 111 and the second input/output terminal 112, and the first input/output terminal 111 and the second input/output terminal 112 may form the both ends of the busbar main body 110 of the busbar unit 100.

The first input/output terminal 111 may be electrically connected to the outside, and the second input/output terminal 112 may be electrically connected to the load. To be connected in this way, the second input/output terminal 112 may be formed to be opposite to the first input/output terminal 111. Power and signals may be transmitted in one direction or two directions through the first input/output terminal 111 and the second input/output terminal 112, and thus operations according to the supply of power and transmission of the control signal to the load are possible.

As needed, the busbar unit 100 may further include a busbar stepped portion 113. The busbar stepped portion 113 may form a step between the first input/output terminal 111 and the second input/output terminal 112. The busbar stepped portion 113 may be formed to not excessively deform the electrical characteristics of the busbar unit 100 and prevent mechanical defects from occurring, and a bending angle at which the busbar stepped portion 113 is bent may be an acute angle or a right angle. The bending structure of the busbar unit 100 and the busbar main body 110 by the busbar stepped portion 113 can shorten a length of the integrated noise filter 1 according to the disclosed embodiment of the present disclosure in a longitudinal direction (e.g., a direction corresponding to an x-axis in the busbar unit 100 illustrated in FIG. 7) and miniaturize the integrated noise filter 1.

Meanwhile, the busbar stepped portion 113 may be formed at a position closer to the first input/output terminal 111 of the busbar main body 110. For example, a first bending distance d1 from the busbar stepped portion 113 to an end of the first input/output terminal 111 may be formed to be shorter than a second bending distance d2 from the busbar stepped portion 113 to an end of the second input/output terminal. In this case, the first bending distance d1 may be a horizontal distance from the busbar stepped portion 113 to the end of the first input/output terminal 111, and the second bending distance d2 may be a horizontal distance from the busbar stepped portion 113 to the end of the second input/output terminal 112. Accordingly, since each of the first input/output terminal 111 and the second input/output terminal 112 is exposed from the case unit 200 by a predetermined area or a predetermined length, the first input/output terminal 111 and the second input/output terminal 112 can be stably electrically connected to the outside and the load.

In addition, in the integrated noise filter 1 according to the disclosed embodiment of the present disclosure, the busbar unit 100 may further include the busbar branch part 120. The busbar branch part 120 may be formed to protrude a predetermined length from one side of the busbar main body 110 including the first input/output terminal 111 and the second input/output terminal 112. For example, the busbar branch part 120 may include a core unit partition portion 121 formed to protrude from the one side of the busbar main body 110 to form a first angle, and a core unit guiding portion 122 formed to protrude from an end of the core unit partition portion 121 to form a second angle. For example, the first angle formed by the core unit partition portion 121 and the busbar main body 110 and the second angle formed by the core unit guiding portion 122 and the core unit partition portion 121 may each be a right angle (90°), but are not necessarily limited to the disclosed value. In this case, at least a part of the busbar branch part 120 may be formed to extend in a direction from the second input/output terminal 112 to the first input/output terminal 111. For example, the core unit guiding portion 122 of the busbar branch part 120 may be formed to extend from the second input/output terminal 112 in a negative x-axis direction toward the first input/output terminal 111. As illustrated in FIG. 7, the busbar branch part 120 is illustrated as being formed by being branched from the one side of the busbar main body 110, but as needed, the busbar branch part 120 may be formed by being branched from both sides of the busbar main body 110, and the core unit guiding portion 122 may be formed by extending in both directions of a positive x-axis direction and the negative x-axis direction.

Referring to FIGS. 3 to 5, 7, 14, and the like, in the integrated noise filter 1 according to the disclosed embodiment of the present disclosure, the at least one core unit 300 may include the first core unit 310 and the second core unit 320. For example, the at least one core unit 300 may include the first core unit 310 which applies the first inductance L1 to the busbar unit 100. As another example, the at least one core unit 300 may include the second core unit 320 which applies the second inductance L2 to the busbar unit 100. The first core unit 310 may be disposed relatively adjacent to the first input/output terminal 111, and the second core unit 320 may be disposed relatively adjacent to the second input/output terminal 112.

In addition, the first core unit 310 and the second core unit 320 may be disposed to be spaced apart from each other in a longitudinal direction (or an axial direction, for example, in a direction parallel to the x-axis). More specifically, the first core unit 310 and the second core unit 320 may be disposed to be spaced apart from each other by the busbar branch part 120. For example, the first core unit 310 may be inserted from the first input/output unit 111 side to the second input/output unit 112. In this case, the first core unit 310 may be guided by the core unit guiding portion 122. The second core unit 320 may be inserted from the second input/output unit 112 side to the first input/output unit 111. The first core unit 310 and the second core unit 320 can be prevented from being in physical contact with each other by the core unit partition portion 121 of the busbar branch part 120.

The first core unit 310 and the second core unit 320 may form a concentric structure, and each of the first core unit 310 and the second core unit 320 may be formed to be spaced apart from the busbar unit 100. That is, the first core unit 310 and the second core unit 320 included in the at least one core unit 300 each have a communication hole, and an inner circumferential surface of each of the first core unit 310 and the second core unit 320, which is formed by the communication holes of the first core unit 310 and the second core unit 320, can be prevented from being in direct contact with the outer surface of the busbar unit 100. Accordingly, the at least one core unit 300 has an advantage of being capable of stably applying the inductance L to the power and signals which move in the busbar unit 100.

Hereinafter, the case unit 200 will be described.

Referring to FIGS. 2, 3, and 9, the case unit 200, which is a component of the integrated noise filter 1 according to the disclosed embodiment of the present disclosure, can protect at least a part of the busbar unit 100, the at least one core unit 300, and the at least one energy storage unit 400 from the external environment.

More specifically, to protect the busbar unit 100 from the external environment, the case unit 200 may include a first busbar unit accommodation part 210 which accommodates the first input/output terminal 111 of the busbar unit 100, and a second busbar unit accommodation part 220 which accommodates the second input/output terminal 112 of the busbar unit 100. As needed, the first busbar unit accommodation part 210 and the second busbar unit accommodation part 220 may be formed so that the first input/output terminal 111 and the second input/output terminal 112 of the busbar unit 100 may be easily joined to a power source or a load.

The first busbar unit accommodation part 210 and the second busbar unit accommodation part 220 may each be formed to be open in a direction corresponding to a different axis. For example, the first busbar unit accommodation part 210 may be formed to be open upward (e.g., in a positive z-axis direction) to accommodate the first input/output terminal 111 of the busbar unit 100. In this case, one surface of the first input/output terminal 111 may be exposed to the outside and may be joined to another device (a power source or a load) through the exposed portion of the first input/output terminal 111. As another example, the second busbar unit accommodation part 220 may be formed to be open in a horizontal direction (e.g., in the positive x-axis direction) to accommodate the second input/output terminal 112 of the busbar unit 100. In this case, both surfaces of the second input/output terminal 112 may be exposed to the outside and may be joined to another device (a power source or a load) through the exposed portion of the second input/output terminal 112.

In addition, the case unit 200 may include a core unit accommodation part 230. As an example, the core unit accommodation part 230 of the case unit 200 may accommodate the at least one core unit 300 so that the center of the at least one core unit 300 corresponds to the center of the busbar unit 100 in the axial direction. By the core unit accommodation part 230, the at least one core unit 300 (which may be, in particular, the second core unit in the integrated noise filter according to the disclosed embodiment of the present disclosure) may be aligned to be disposed coaxially with a center axis of the busbar unit 100.

Meanwhile, the core unit accommodation part 230 may be formed to be open in a direction corresponding to the same axis as the second busbar unit accommodation part 220. That is, the core unit accommodation part 230 may be formed to be open in the horizontal direction (e.g., in the positive x-axis direction) and may accommodate the second core unit 320 of the at least one core unit 300. Thereafter, the second core unit 320 may be molded to be protected from the external environment.

In addition, the case unit 200 may further include energy storage unit accommodation parts 240. The energy storage unit accommodation part 240 may accommodate the at least one energy storage unit 400. For example, the energy storage unit accommodation part 240 may be formed in a pair to face each other based on the center of the case unit 200. More specifically, the energy storage unit accommodation parts 240 may include a first energy storage unit accommodation part 241 for accommodating the first energy storage unit 410 among the at least one energy storage unit 400, and a second energy storage unit accommodation part 242 for accommodating the second energy storage unit 420 among the at least one energy storage unit 400.

Meanwhile, to miniaturize and integrate the integrated noise filter 1 according to the disclosed embodiment of the present disclosure, the energy storage unit accommodation part 240 may be formed to be open in a direction corresponding to the same axis (e.g., the z-axis) as the first busbar unit accommodation part 210 and formed to be open in a direction corresponding to a different axis from the second busbar unit accommodation part 220. That is, the energy storage unit accommodation part 240 may be formed to be open in a vertical direction. Accordingly, a structure in which the at least one energy storage unit 400 is stably assembled and soldered on a surface (e.g., a surface corresponding to an xy plane) of the busbar unit 100 may be formed.

Additionally, the energy storage unit accommodation part 240 may be formed to be open in a direction opposite to the first busbar unit accommodation part 210. More specifically, the first busbar unit accommodation part 210 may be formed to be open in the positive z-axis direction, and the energy storage unit accommodation part 240 may be formed to be open in a negative z-axis direction. In the structure of the busbar unit 100 including the busbar stepped portion 113, a position at which the energy storage unit accommodation part 240 is formed can be determined to be accommodated adjacent to a layer corresponding to the second input/output terminal 112 so that the at least one energy storage unit 400 may be easily coupled to a part of the busbar unit 100 and a grounding unit to be described below. Accordingly, there is an advantage that the at least one energy storage unit 400 can be stably accommodated in the energy storage unit accommodation part 240 and easily electrically connected to the busbar unit 100, thereby effectively reducing noise.

Hereinafter, the grounding unit 500 will be described.

Referring to FIGS. 8, 9, 13, and 15, the integrated noise filter 1 according to the disclosed embodiment of the present disclosure may further include a pair of grounding units 500. The pair of grounding units 500 may be electrically connected to at least a part of the busbar unit 100 to form a ground. In this case, a grounding method of the pair of grounding units 500 may be frame grounding (FG), but is not necessarily limited thereto.

The pair of grounding units 500 may include the first grounding unit 510 and the second grounding unit 520. In this case, the first grounding unit 510 of the pair of grounding units 500 may be electrically connected to the busbar branch part 120 by both ends of the first energy storage unit 410 of the at least one energy storage unit 400 to form a first grounding path. In addition, the second grounding unit 520 of the pair of grounding units 500 may be fastened to the first input/output terminal 111 of the busbar unit 100 and electrically connected to the first input/output terminal fastening unit 600 fastened to the first input/output terminal 111 of the busbar unit 100 and formed to protrude to one side thereof by both ends of the second energy storage unit 420 to form a second grounding path.

A first input/output terminal fastening unit 600 may be formed in a structure that may be coupled to a through hole formed in at least a part of the first input/output terminal 111 of the busbar unit 100, and for example, the first input/output terminal fastening unit 600 may be formed in at least one of known coupling structures, such as a screw coupling structure, a rivet coupling structure, and a forcibly-fitting coupling structure. Meanwhile, in the integrated noise filter 1 according to the disclosed embodiment of the present disclosure, the capacitor connection unit 700 may be formed to protrude from one side of the first input/output terminal fastening unit 600. The capacitor connection unit 700 is formed so that the at least one energy storage unit 400 may form a stable connection structure between the capacitor connection unit 700 and the second grounding unit 520.

In addition, the case unit 200 may further include each of a pair of grounding unit accommodation parts 250 for accommodating one of the pair of grounding units 500. The pair of grounding unit accommodation parts 250 may be formed to be open in a direction corresponding to the same axis as the second busbar unit accommodation part 220 for accommodating the second input/output terminal 112 of the busbar unit 100. By the pair of grounding unit accommodation parts 250, at least one of the pair of grounding units 500 may be exposed in one direction (e.g., the positive x-axis direction) and may be in contact with a specific frame to form a grounding structure.

Referring to FIGS. 4 and 13 to 15, the integrated noise filter 1 according to the disclosed embodiment of the present disclosure may further include an elastic member 800. The elastic member 800 may be disposed between a part of the inner surface of the case unit and the at least one core unit 300 when the at least one core unit 300 is accommodated in the core unit accommodation part 230 of the case unit 200 and then molded. For example, the elastic member 800 may be formed in a ring shape and formed of a urethane material. After the elastic member 800 is disposed, a space between the elastic member 800 and the at least one core unit 300 may be molded to form a structure in which the molded outer surface of the at least one core unit 300 and a part of the inner surface of the case unit 200 are elastically supported without being in direct contact with each other. Accordingly, the integrated noise filter 1 according to the disclosed embodiment of the present disclosure has an advantage of being capable of being stably assembled while having a miniaturized structure.

Hereinafter, an integrated noise filter 2 according to another disclosed embodiment of the present disclosure will be described. In describing the integrated noise filter 2 according to another disclosed embodiment of the present disclosure, different components from the integrated noise filter 1 according to the one disclosed embodiment of the present disclosure will be mainly described, and descriptions of the same components as the integrated noise filter 1 according to the one disclosed embodiment of the present disclosure will be omitted.

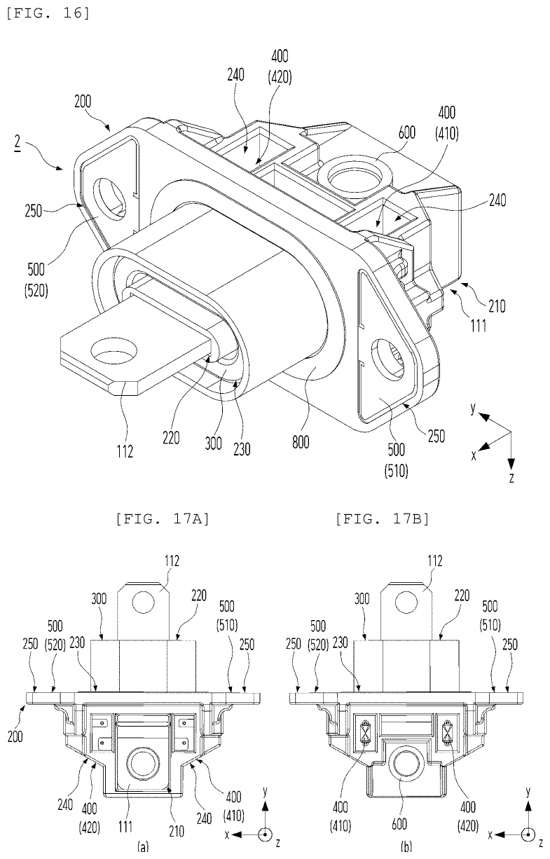

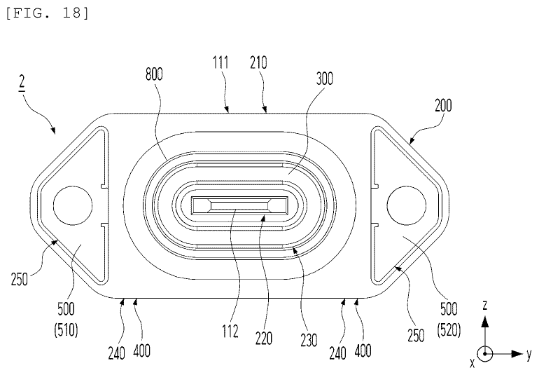

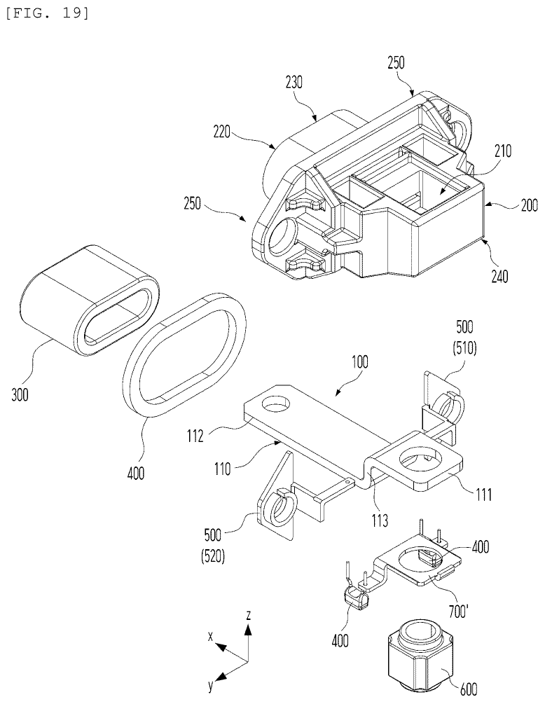

FIG. 16 is a perspective view of the integrated noise filter 2 according to another disclosed embodiment of the present disclosure, FIG. 17A is a top view of the integrated noise filter 2 according to another disclosed embodiment of the present disclosure, and FIG. 17B is a bottom view of the integrated noise filter 2 according to another disclosed embodiment of the present disclosure, and FIG. 18 is a front view of the integrated noise filter 2 according to another disclosed embodiment of the present disclosure. In addition, FIG. 19 is an exploded perspective view of the integrated noise filter 2 according to another disclosed embodiment of the present disclosure.

Referring to FIGS. 16 to 19 (in particular, FIG. 19), the integrated noise filter 2 according to another disclosed embodiment of the present disclosure may include only one core unit 300. In the integrated noise filter 2 according to another disclosed embodiment of the present disclosure, since no problem that the plurality of core units (e.g., the first core unit and the second core unit) are in physical contact with each other occurs, the configuration of the busbar branch part 120 may be omitted.

In addition, the integrated noise filter 2 according to another disclosed embodiment of the present disclosure may include the pair of grounding units 500 in the same manner as the above-described contents. However, the structure of forming a grounding path by the at least one energy storage unit 400 is different partially.

More specifically, the pair of grounding units 500 are electrically connected to at least a part of the busbar unit 100 to form a ground. In this case, the first grounding unit 510 of the pair of grounding units 500 may be electrically connected to one end of a capacitor connection unit 700′ fixed by the first input/output terminal fastening unit 600 of the first input/output terminal 111 of the busbar unit 100 by both ends of the first energy storage unit 410 of the at least one energy storage unit 400 to form the first grounding path, and the second grounding unit 520 of the pair of grounding units 500 may be electrically connected to the other end of the capacitor connection unit 700′ by both ends of the second energy storage unit 420 of the at least one energy storage unit 400 to form the second grounding path.

That is, the capacitor connection unit 700′ may have a through-hole structure having a shape corresponding to the first input/output terminal 111 and may be coupled to the first input/output terminal 111 by the first input/output terminal fastening unit 600. In addition, there is an advantage that the at least one energy storage unit 400 can be stably assembled and soldered with the pair of grounding units 500 by the structure formed to protrude from the both ends of the capacitor connection unit 700′.

Although exemplary embodiments of the present disclosure have been described above, the present disclosure is not limited thereto and may be modified in any form within the scope of the claims, the detailed description of the present disclosure, and the accompanying drawings, and it is apparent that the modifications also fall within the scope of the present disclosure.

### INDUSTRIAL APPLICABILITY

The present disclosure provides an integrated noise filter which is capable of being integrated and miniaturized, thereby improving assemblability and stability and miniaturizing the overall power conversion device.

1. An integrated noise filter comprising:
a busbar unit which transmits power and an electrical signal;
a case unit which accommodates and covers at least a part of the busbar unit;
at least one core unit which covers a part of an outer surface of the busbar unit and imparts inductance to the busbar unit; and
at least one energy storage unit electrically connected to the busbar unit to impart capacitance to the busbar unit.

2. The integrated noise filter of claim 1, wherein the busbar unit includes a first input/output terminal electrically connected to an outside, and a second input/output formed terminal opposite to the first input/output terminal and electrically connected to a load.

3. The integrated noise filter of claim 2, wherein the busbar unit further includes a busbar stepped portion which forms a step between the first input/output terminal and the second input/output terminal, and
a first bending distance from the busbar stepped portion to an end of the first input/output terminal is shorter than a second bending distance from the busbar stepped portion to an end of the second input/output terminal.

4. The integrated noise filter of claim 2, wherein the busbar unit further includes a busbar branch part formed to protrude a predetermined length from one side of a busbar main body including the first input/output terminal and the second input/output terminal, and
at least a part of the busbar branch part is formed to extend in a direction from the second input/output terminal to the first input/output terminal.

5. The integrated noise filter of claim 4, wherein the core unit includes:
a first core unit configured to apply first inductance to the busbar unit; and
a second core unit configured to apply second inductance to the busbar unit, and
the first core unit and the second core unit are disposed to be spaced apart from each other by the busbar branch part.

6. The integrated noise filter of claim 5, wherein the first core unit and the second core unit form a concentric structure, and each of the first core unit and the second core unit is formed to be spaced apart from the busbar unit.

7. The integrated noise filter of claim 2, wherein the case unit includes:
a first busbar unit accommodation part which accommodates the first input/output terminal of the busbar unit; and
a second busbar unit accommodation part which accommodates the second input/output terminal of the busbar unit.

8. The integrated noise filter of claim 7, wherein the first busbar unit accommodation part and the second busbar unit accommodation part are each formed to be open in a direction corresponding to a different axis.

9. The integrated noise filter of claim 7, wherein the case unit further includes a core unit accommodation unit accommodating the at least one core unit so that a center of the at least one core unit corresponds to a center of the busbar unit in an axial direction, and
the core unit accommodation part is formed to be open in a direction corresponding to the same axis as the second busbar unit accommodation part.

10. The integrated noise filter of claim 7, wherein the case unit further includes an energy storage unit accommodation part which accommodates the at least one energy storage unit, and
the energy storage unit accommodation unit is formed to be open in a direction corresponding to the same axis as the first busbar unit accommodation part and formed to be open in a direction corresponding to a different axis from the second busbar unit accommodation part.

11. The integrated noise filter of claim 10, wherein the energy storage unit accommodation part is formed to be open in a direction opposite to the second busbar unit accommodation part.

12. The integrated noise filter of claim 4, further comprising a pair of grounding units electrically connected to at least a part of the busbar unit to form a ground,
wherein a first grounding unit of the pair of grounding units is electrically connected to the busbar branch part by both ends of the first energy storage unit of the at least one energy storage unit to form a first grounding path, and
a second grounding unit of the pair of grounding units is electrically connected to a first input/output terminal fastening unit fastened to the first input/output terminal of the busbar unit by both ends of the second energy storage unit of the at least one energy storage unit and formed to protrude to one side thereof to form a second grounding path.

13. The integrated noise filter of claim 12, wherein the case unit further includes a pair of grounding unit accommodation parts which are formed to be open in a direction corresponding to the same axis as the second busbar unit accommodation part accommodating the second input/output terminal of the busbar unit and each accommodate one of the pair of grounding units.

14. The integrated noise filter of claim 2, further comprising a pair of grounding units electrically connected to at least a part of the busbar unit to form a ground,
wherein a first grounding unit of the pair of grounding units is electrically connected to one end of a capacitor connection unit, which is fixed to the first input/output terminal of the busbar unit by the first input/output terminal fastening unit, by both ends of the first energy storage unit of the at least one energy storage unit to form a first grounding path, and
a second grounding unit of the pair of grounding units is electrically connected to the other end of the capacitor connection unit by both ends of the second energy storage unit of the at least one energy storage unit to form a second grounding path.

15. The integrated noise filter of claim 1, wherein the at least one core unit is accommodated in the case unit and then molded, and a ring-shaped elastic member is disposed between a part of an inner surface of the case unit and a molded outer surface of the at least one core unit.
